(19) United States
(12) Patent Application Publication
(10) Pub. No.: US 2007/0210940 A1
(43) Pub. Date: Sep. 13, 2007

(54) Method of efficient direct sequence spread spectrum signal encoding and apparatus therefore

(76) Inventor: Leslie Rubinstein, KNOXVILLE, MD (US)

Correspondence Address: Leslie Rubinstein, 114 Galyn Drive, Knoxville, MD, 21758, US

(21) Appl. No.: 11/547,918

(22) PCT Filed: Apr. 5, 2005
(86) PCT No.: PCT/CA05/00503

§ 371 Date: Oct. 6, 2006

Related U.S. Application Data
(60) Provisional application No. 60/558,988, filed on Apr. 5, 2004.

(51) Int. Cl. H03M 7/00

(52) U.S. Cl. 341/50

(57) ABSTRACT

A method and system for spread spectrum encoding and decoding of data is disclosed relying on a look-up table. A stream of bits are received for being one of encoded and decoded. The bits are segmented into words of a predetermined size. For each word, a value is determined from a look-up table. Optionally the look-up table is sequential in nature allowing for each word to be indexed within a different sequential look-up table from a plurality of sequential look-up tables.

### FIELD OF THE INVENTION

The invention relates to encoding of signals for robust communication thereof and more particularly to a method for creating an intermediate stage direct spread spectrum signal (DSSS) encoding and decoding system and an apparatus therefore.

### BACKGROUND OF THE INVENTION

Spread Spectrum encoding and decoding is well known in the art. In spread spectrum encoding, a signal is spread across a spectrum prior to transmission and then decoded upon being received. Thus the signal power remains approximately same but is provided over a wider band and any specific signal within the wideband that is interfering in nature gets spread during the decoding process resulting in a reconstruction of the despread signal.

In DSSS, signals are spread by mapping a single value onto a plurality of values within a data stream and transmitting those values. During decoding, the signal is reconstituted as negative and positive values. By using a spreading methodology as is known in the art, a signal other than one spread using a predetermined spreading code, when decoded, results in little or no extracted signal. As such, these signals also fail to interfere substantially with the encoded signal.

Current methods for spreading of signals in DSSS encoders, process each bit to determine a resulting encoded spread data value. This process relies on a spreading code that often requires significant computation. Further, the spreading code mathematically must meet predetermined criteria in order to ensure that it achieves noise isolation, inter-symbol isolation, that it is not ambiguous in nature and so forth. Thus, design and implementation of spreading codes is a field of study.

It would be highly advantageous to provide a method of DSSS that does not involve computationally intensive spreading codes and that supports noise isolation, inter-symbol isolation, and that it is not ambiguous.

### SUMMARY OF THE INVENTION

It is therefore an object of the present invention to provide a lookup table based method of DSSS and an apparatus therefore.

In accordance with the invention there is provided a method of encoding of data for spread spectrum transmission thereof comprising: providing a memory having lookup tables therein; receiving digital data; retrieving from the lookup tables based on the input data a value for use in spreading the data to form a code word; spreading the input data according to the lookup table to form the code word; and, after suitable further processing, generating an RF signal derived from the code word.

In accordance with another aspect of the invention there is provided a method of decoding spread spectrum encoded data comprising: providing a memory having lookup tables therein; receiving an RF signal including a digital spread spectrum signal encoded therein; and, using lookup tables to decode the encoded digital spread spectrum signal to determine a value or values encoded to form the encoded spread spectrum signal; the values encoded provided as output values from the decoder.

In accordance with another aspect of the invention there is provided a data encoder for spread spectrum encoding comprising: means for providing a memory having lookup tables therein; means for receiving digital data; means for retrieving from the lookup tables based on the input data a value for use in spreading the data to form a code word; means for spreading the input data according to the lookup table to form the code word; and, means for processing the data and using it to generate an RF signal derived from the code word.

In accordance with yet another aspect of the invention there is provided decoders for decoding of spread spectrum encoded data comprising: means for providing a memory having lookup tables therein; means for receiving an RF signal including a digital spread spectrum signal encoded therein; and, means for using lookup tables to decode the encoded digital spread spectrum signal to determine a value or values encoded to form the encoded spread spectrum signal; the value encoded provided as an output value from the decoder.

The inventive method advantageously supports multi-bit symbols being sent with fewer bits than would be required by the use of a conventional spreading method

### BRIEF DESCRIPTION OF THE DRAWINGS

The invention is now described with reference to the figures in which:

FIG. 1a is a graphical representation of a signal prior to spread spectrum encoding;

FIG. 1b is a graphical representation of a signal after spread spectrum encoding;

FIG. 1c is a graphical representation of a spread spectrum encoded signal after decoding thereof;

FIG. 2 is a simplified block diagram of a DSSS digital modulation transmitter;

FIG. 3 is a simplified block diagram of a DSSS digital modulation receiver;

FIG. 4a is a simplified flow diagram of a method of DSSS encoding;

FIG. 4b is a simplified flow diagram of an alternative method of DSSS encoding;

FIG. 5 is a simplified flow diagram of a method of DSSS decoding;

FIG. 6 is a simplified diagram of a code word table structure including a plurality of blocks and a lookup table within each block; and,

FIG. 7 is a simplified diagram of encoded data including a plurality of spread spectrum bits related to each bit in the input data.

### DETAILED DESCRIPTION OF AN EMBODIMENT OF THE INVENTION

Though spread spectrum encoding and decoding are well known in the art, prior art digital implementations have relied on computationally intensive encoding and decoding processes. In these processes, each bit is processed in sequence in dependence upon a pseudo-random bit sequence and a current bit value. Thus, the first bit in a data stream may be encoded differently than the sixth bit in the same data stream. This variability in encoding allows for implementation of encoding structures providing improved error detection/correction and improved noise filtering. Thus the prior art methods receive a single bit of data and convert that bit into a plurality of encoded bits—typically 16—for transmission.

According to the invention, a method for direct sequence spread spectrum encoding of high speed digital data is presented using lookup tables and thereby reducing the computational load. Such a method has advantages when applied to encoding and decoding of extremely high speed (1 MbS+) digital data. Further, since the method does not rely on a general algorithm, but instead relies on predetermined values, optionally the data is encoded with a higher efficiency depending upon the application and the desired encoding characteristics. That is to say, the lookup table values can be determined using algorithms far too complex to be implemented in real-time at the required data rates. Additionally, this method allows lookup values to be chosen so that multiple bits are encoded at the same time, while more than one receiver can be used to decode all or part of the data. This means that different data can be transmitted simultaneously to different receivers.

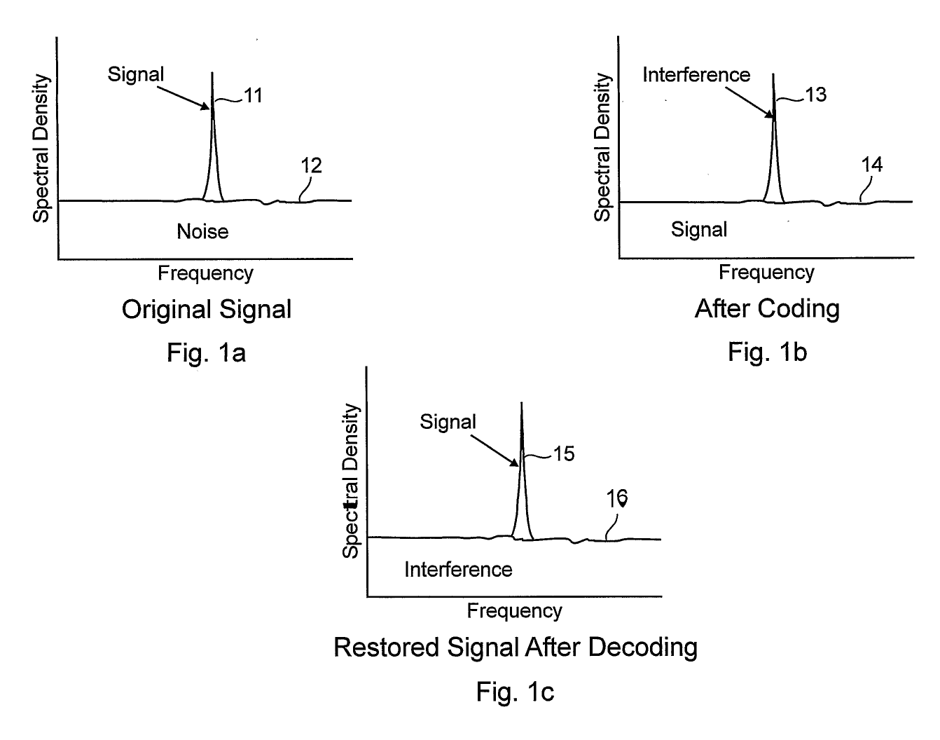

Referring to FIG. 1a, a graphical representation of a signal is presented. The signal 11 is shown as a peak having a narrow bandwidth and rising out of a noise floor 12. It is important that the peak have at least a predetermined presence above the noise floor to ensure that it is detectable. The signal 11 is provided to a spread spectrum encoder for encoding thereof.

Referring to FIG. 1b, a graphical representation of the signal once encoded is shown. Here, the signal and the noise are encoded through a process of spreading resulting in a spread spectrum signal 14. The signal has similar power to the signal of FIG. 1a but spread out instead of concentrated within a single peak. Also shown in FIG. 1b is an interference signal 13. The interference signal is, for example, another signal transmitted by another device and received by a same receiver as receives the spread spectrum signal 14 for spread spectrum decoding. The signal of FIG. 1b, when received is decoded.

Referring to FIG. 1c, shown is the decoded signal 15 having a noise floor 16. The interference signal 14 is spread within the noise by the decoding process. The noise 12 is restored within the decoded signal. Thus the noise floor 16 is different than the noise floor 12 in relation to a power of the interference signal 13 and also to local noise detected by the receiver from other local and distant sources. It is highly desirable that the signal 15 be very similar to the signal 11.

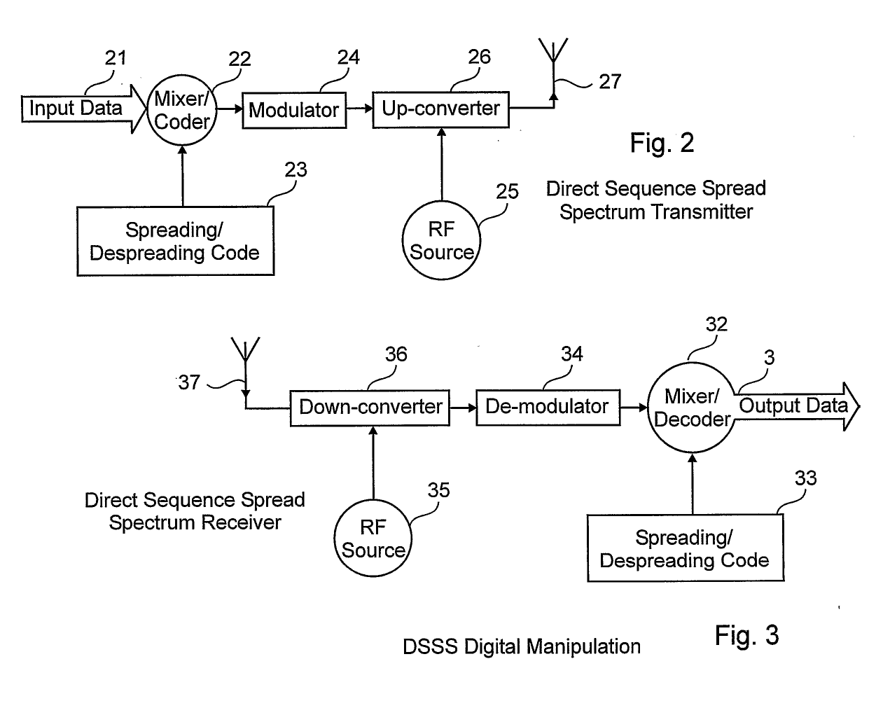

Referring to FIG. 2, a simplified block diagram of a DSSS digital modulation encoding apparatus is shown. The apparatus includes an input port 21 for receiving of digital data for transmission. The received digital data is provided to a mixer coder circuit 22 along with spreading code 23. The mixer/coder 22 encodes the digital data and provides digital spread spectrum data to a modulator 24. The modulator 24 modulates an RF signal from an RF source 25 that is up-converted by up-converter 26. The modulated signal is provided to antenna 27 for transmission therefrom.

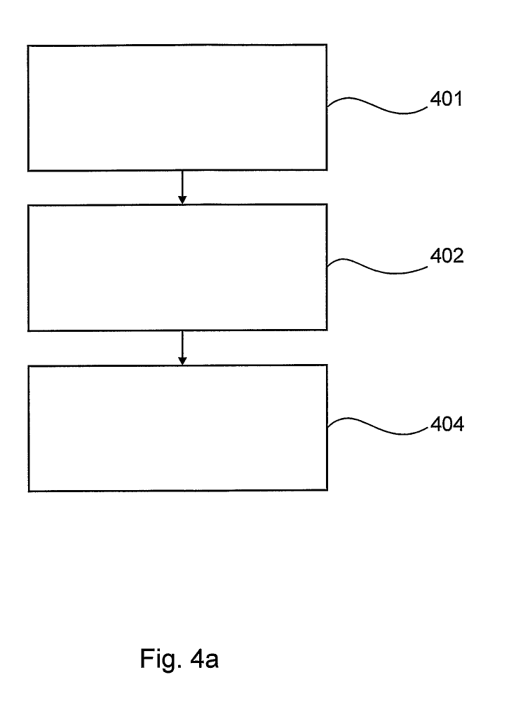

Referring to FIG. 3, a simplified block diagram of a DSSS digital modulation decoding apparatus is shown. A signal is received at antenna 37. The signal is down-converted in down-converter 36 based on an RF signal provided from RF source 35. The down-converted signal is demodulated by demodulator 34 and provided to mixer/decoder 32 for decoding thereof. The decoding operation is performed in dependence upon spreading/despreading code 33 to provide an output digital signal at output port 31.

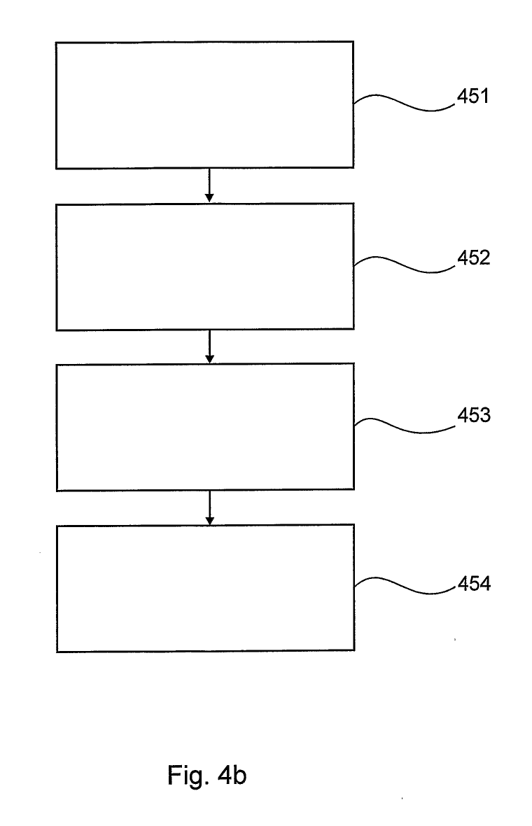

Referring to FIG. 4a, a method of DSSS encoding is shown in simplified flow diagram. Data for encoding is received as a series of data words in a parallel fashion at step 401. The example data word length shown is a 16-bit data word. Optionally another length of 1 or more is chosen. As each data word is received, it addresses a location in a lookup table that is indexed according to the data word location within a sequence—word number—and the data word value—word value—at step 402. Thus, even if the 14^{th} and 15^{th} data words are identical, different locations within the lookup table are referenced because the word number is different. The word number indexes blocks of 2¹⁶ values and the word value indexes a memory location within the indexed block.

At step 404, the spreading code word that corresponds to our original data word is modulated. In accordance with common prior art techniques, this code drives a mixer directly to produce a DSSS signal. Alternatively, at step 454, a direct digital sequence (DDS) modulator is used. A DDS modulator allows for parallel data input to specify an instantaneous voltage level of a modulated signal. The parallel data is applied to a lookup table coupled to a D/A converter, which produces an analog voltage that corresponds to the input value. This allows for precise control of frequency and phase of the output signal, and allows for a much more precise and accurate signal than is possible using conventional modulation methods. Thus, the 64 bit spreading code word is provided to access a lookup table and obtain values for modulating a DDS at a frequency and phase to generate a unique RF signal, which can then be amplified and filtered prior to transmission thereof. Optionally, the use of DDS allows for alteration of modulation methods by changing the input values to the DDS or the lookup table within the DDS.

Referring to FIG. 4b, a method of DSSS encoding is shown in simplified flow diagram. Data for encoding is received as a series of data words in a parallel fashion at step 451. The data word length shown is a 16-bit data word. As each data word is received, it is used to address a plurality of locations in at least a lookup table that is indexed according to the data word location within a sequence—word number—and the data word value—word value at step 452. Thus, even if the 14^{th} and 15^{th} data words are identical, different locations within the lookup table are referenced because the word number is different. Here, for each data word, two lookup tables are employed, one for the first 8 bits and another for the second 8 bits. In the embodiment of FIG. 4a, each block within the lookup table is 2¹⁶ bits long and a fixed number of blocks, for example 4096 is employed. By dividing the word into 2 8-bit indices, each block has 2⁸ bits. Of course, more blocks are required, on the order of 8192. This results in a total reduction in size of the lookup table on the order of 1/128^{th}.

At step 453, the two values retrieved from the lookup tables are combined. Thus, some extra processing and an extra memory retrieval operation are used to reduce the memory requirements. Preferably, the lookup table entries are selected for being combined by simple fixed-point arithmetic operations.

The lookup table consists of a fixed number of blocks for performing encoding. As such, the encoding process is cyclical in nature returning to the first block after completing processing with each block. For example, if a lookup table contains 4096 blocks, the first 4096 data words result in obtaining code words from each of the 4096 unique blocks, but the 4097^{th} data word retrieves its code word from the first block. This is equivalent of using a code-generating algorithm that generates a pseudo-random code with a repetition rate of 65536. With a singular goal of generating code words that spread the signal uniqueness is not a requirement. In fact the finite nature of the lookup tables allows for truly orthogonal multi-rate codes, since the code words in question are optionally generated and verified for specific properties.

A characteristic of the encoding process is that it must be capable of uniquely encoding a stream of data such that decoding is unambiguous. With ambiguity, the decoding process is able to determine more than one possible decoded data value for a same received data value. Thus, ambiguity is not desirable. In order to avoid ambiguity, uniqueness of code words as they relate to input data words is ensured. When a single lookup table is employed for each data value, this is a mere matter of ensuring that each entry is unique; however, when a data word is divided into a plurality of segments and the lookup table values are then combined uniqueness should be ensured for each such combination. That is to say, if we segment a 16-bit data word into 2 8-bit segments and retrieve a code word for each of these 8-bit segments, the resulting code word when the two segments are combined is preferably unique, unambiguous, rather than a code word that is obtainable from each of several different combinations of retrieved values.

For example, an 11-bit spreading sequence is one in which every bit in a data word corresponds to 11 bits in a spreading code word. Thus, if the data word is segmented into 16 individual bits and a code word is obtained for each of these bits, 16 11-bit code words result to combine into a single final code word. It is clear to those of skill in the art that a single value formed as a combination of 16 values can be formed as a combination of many different sets of those 16 values (2+2+2+2=8, 1+3+2+2=8, etc.). Thus, absent careful selection of the values, uniqueness does not result. There are a number of different ways to obtain unique combinations of code words, and because the combinations of fixed values are deterministic in nature, a brute force verification of any lookup table is supported to ensure that ambiguity does not result.

An Example of Combining Retrieved Values Follows.

Given a 16-bit data word and a 16-bit spreading sequence—each bit corresponding to a unique 16-bit spreading code. By represent the resulting code word in 64 bits instead of 16 bits, with each 4 bit segment having a binary 1 or a zero, we obtain a series of 16 64-bit code words which are combinable to produce a final 64 bit code word representing the DSSS code word for 16 bits at once, i.e. a parallel code word. For example, if the code sequence for a particular bit was
1011110110011110,
this is represented as
0001 0000 0001 0001 0001 0001 0000 0001 0001 0000 0000 0001 0001 0001 0001 0000.

The 16 unique code words for the 16 bits in the data word are then be added to produce a unique 64 bit code word, specific only to that particular 16-bit data word at that point in the sequence of data. When the data of the original 16-bit data word is segmented into segments larger than 1 bit, i.e. 8 bits, then the final code word is simply the result of combining the corresponding code words for the 8 individual bits combined and stored in the table. Thus, combination of the values retrieved for each 8-bit segment results in the final code word.

By means of a check of a bit of each segment, here the leftmost bit, a determination of sign, inverted or not, is made. When a data bit is correlated to produce a spreading code word, the actual operation carried out is an exclusive-or. In spread spectrum encoding a code word is exclusive-ORed to determine the result. When a codeword is combined with a zero, the result is the original code word, but when it is exclusive-ORed with a 1, the result is the bitwise inverse of the code word. Consequently, only a single table entry is used to represent values and a single bit to represent sign. Preferably, individual retrieved values have been selected for combination without producing overflows or other problematic results.

Alternatively, another method of combining retrieved values may be employed. Once again, due to the finite nature of the lookup table values, it is possible to verify a method of combining retrieved values to ensure proper operation and resulting unambiguity.

At step 454, the spreading code word that corresponds to our original data word is modulated. In accordance with common prior art techniques, this code drives a mixer directly to produce a DSSS signal. For the above example, this results in the 64-bit spreading code word that corresponds to our original 16-bit data word being provided to the mixer. Alternatively, at step 454, a direct digital sequence (DDS) modulator is used. A DDS modulator allows for parallel data input to specify an instantaneous voltage level of a modulated signal. The parallel data is applied to a lookup table coupled to a D/A converter, which produces an analog voltage that corresponds to the input value. This allows for precise control of frequency and phase of the output signal, and allows for a much more precise and accurate signal than is possible using conventional modulation methods. Thus, the 64 bit spreading code word is provided to access a lookup table and obtain values for modulating a DDS at a frequency and phase to generate a unique RF signal, which can then be amplified and filtered prior to transmission thereof. Optionally, the use of DDS allows for alteration of modulation methods by changing the input values to the DDS or the lookup table within the DDS.

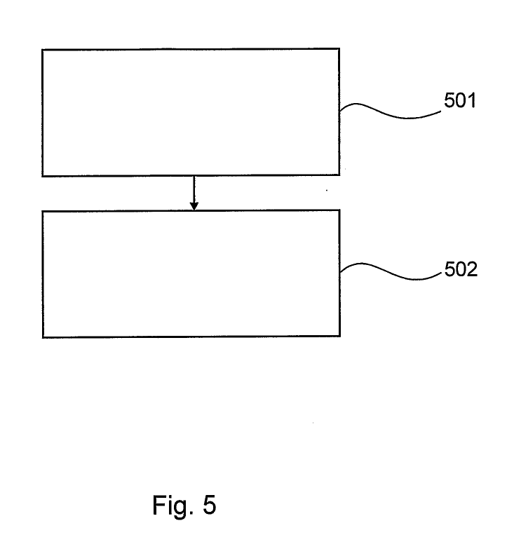

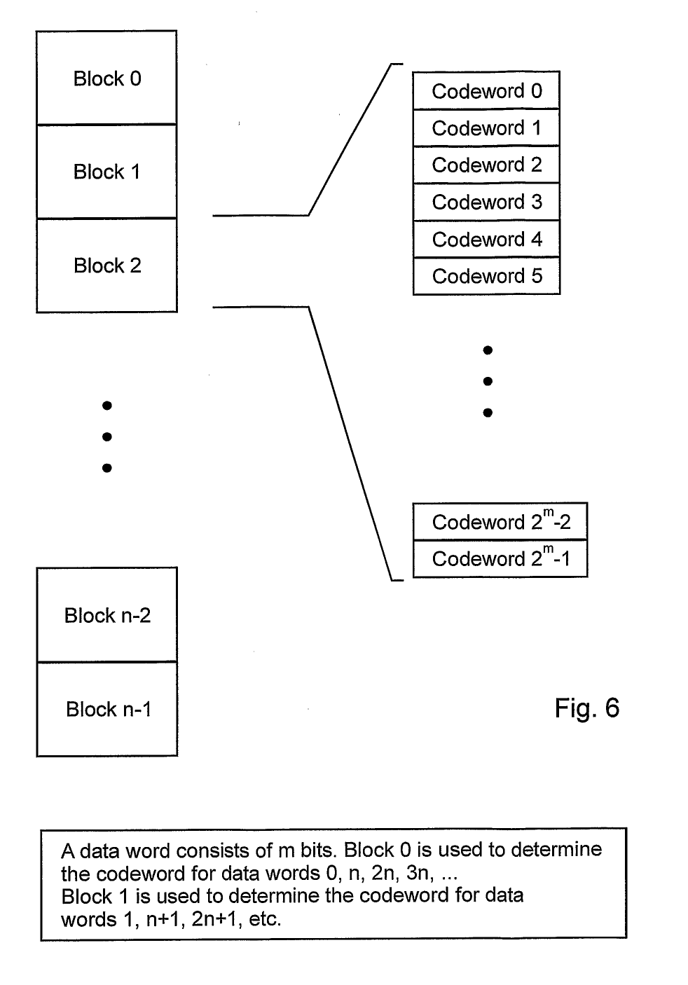

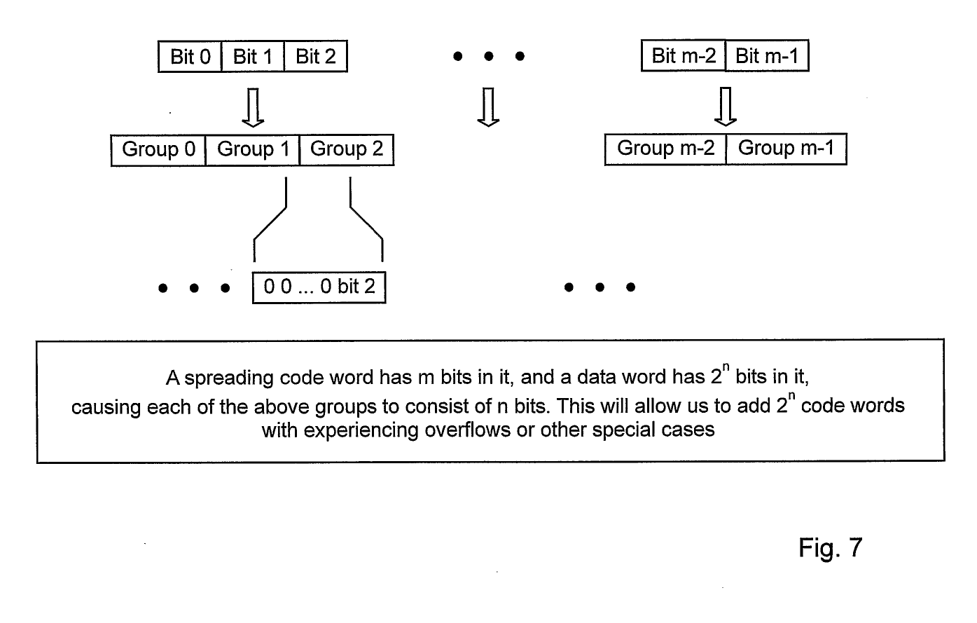

Referring to FIG. 5, a simplified flow diagram of a method of receiving and decoding data as encoded by the method of FIG. 4a is shown. At step 501 the encoded spread spectrum signal is received.

The signal is downconverted and provided to a demodulator for demodulation thereof at step 502. The demodulated signal is then decoded by taking a vector dot product of the received and processed digital signal with the corresponding code words for each separate piece of the data word as stored in the lookup table. The result of the dot product is one of three possibilities. When the result is a large positive or a large negative number, corresponding to a binary one or zero for that section of the code word, it is indicative of potential data. When the result is a small number relatively close to zero, it is indicative of an absence of a signal. Absence of a signal indicates noise or a signal encoded using a different code. The actual magnitude of the values depends on a number of factors, including signal strength and signal quality. Analysis of decoded signals to extract signal data is well known in the art.

By changing the data in the lookup tables any combination of bits are decoded at a time. Thus, in the above example, if each receiver decodes a single bit from the original 16-bit data word, a 16:1 spreading ratio (processing gain) results, since each bit is originally encoded using a 16-bit word.

While the final code word that is generated remains a multiple of the # bits in the data word, this code word is generated in far less time than that using conventional coding methods. Further, by using sophisticated modulation techniques the time it takes to transmit the data is further reduced over conventional modulation techniques. Both of these factors contribute to reducing the time it takes to process and transmit the data and thus supports higher data rates with a given processor based hardware implementation than is possible with prior art conventional techniques.

The above noted method is intended for use with fixed access. As such, there is no problem in correlating the signal; i.e. the data word being transmitted is always known and therefore blocks in our lookup tables are easily identified. Problems relating to multi-user detection are avoided, being fixed access with prescheduled time slots, decoding codes are predetermined obviating any need for lengthy iterative decoding algorithms.

Of course the above method is also applicable to other than fixed access communications including mobile communications and pseudo mobile communications.

Though the above embodiments are described with reference to parallel input data, the invention is also applicable to serial input data and to either processing the data one bit at a time or the use of a shift-register to convert the serial data into parallel data. Of course, when the lookup table indexes on a single bit value (as described above), then the use of serial data is fully supported absent a shift-register.

Though the above embodiments are described with reference to a 16-bit data word, data words of any length are supported and selection of a data word length by one of skill in the art will depend upon a plurality of design parameters and customer goals.

Though the above described embodiment indicates that there is a direct tradeoff between memory usage and processing time, many high speed DSPs are capable of doing several operations in parallel such as the two lookup operations. This results in the two lookup operations and the addition being performed in two operation cycles. This compares extremely favorably with the prior art encoding method that requires each individual bit to be convolved with a multi-bit spreading sequence, requiring a greater number of operations. Further, since a coding algorithm is not used to calculate the spreading sequence as the data is received, computational overhead associated with this is avoided. The method described herein is less computationally intensive than prior art coding methods and consequently is better suited for the encoding and decoding of extremely high speed (1 MbS+) digital data.

Further, the present invention allows for addition of differently encoded signals in the digital domain prior to modulation and transmission thereof. In typical prior art implementations, signals are encoded and modulated such that the modulated signals are combined i.e. superimposed on each other. As such, it is very important to carefully select encoding methodologies to ensure that the signals when combined in the analogue domain are extractable one from the other. The present invention allows for encoding of two different signals and combining in the digital domain the results in a fashion allowing for decoding of the signals separately with no inter-symbol interference. This is highly advantageous as it supports repeatable and predictable inter-symbol isolation allowing for higher signal density within a same area.

Since the method allows each bit of the original input data to be decoded separately, it provides the same noise immunity and suppression as do conventional spread spectrum methods.

Numerous other embodiments may be envisaged without departing from the spirit or scope of the invention.

What is claimed is:

1. A method of encoding data for spread spectrum transmission thereof comprising:
providing a memory having a lookup table therein;
receiving digital data including a data word;
retrieving from the lookup table a value for use in transforming the data word to form a code word;
transforming the data word according to the retrieved lookup table value to form the code word; and,
generating an RF signal derived from the code word.

2. A method according to claim 1, wherein the lookup table comprises a plurality of blocks, each block including a group of data values for being accessed according to the value of the digital data and a position of the digital data within an input data stream.

3. A method according to claim 2, wherein a block consists of those values in the lookup table organized in such a way as to be accessed by a particular data word depending on the position of the data word within the input stream.

4. A method according to claim 3 wherein the lookup table values are retrieved based on numerical ordering.

5. A method according to claim 3, wherein the lookup table values are retrieved based on a hashing of the digital data.

6. A method according to claim 3, wherein the lookup table values are retrieved based on an index table.

7. A method according to claim 1, wherein the lookup table comprises a plurality of blocks, each block is for being indexed by a digital data number and an address within each block for being indexed by the digital data value and wherein retrieving includes indexing the lookup table based on the data word number to determine a plurality of blocks therein and indexing each of the determined plurality of blocks based on a segment of the data word value to retrieve from each indexed location within the lookup table values; and using the values to determine the codeword.

8. A method according to claim 1, wherein transmitting an RF signal includes modulating of an RF signal based on the code word and transmitting the modulated RF signal.

9. A method according to claim 8 wherein the RF signal is generated from the code words with a direct digital sequence (DDS) modulator.

10. A method of decoding of data for spread spectrum encoded data comprising:
providing a memory having a lookup table therein;
receiving an RF signal including a digital spread spectrum signal encoded therein; and,
using a lookup table to decode the encoded digital spread spectrum signal to determine at least some of the values encoded to form the encoded spread spectrum signal; the value encoded provided as an output value from the decoder.

11. A data encoder for spread spectrum encoding comprising:
means for providing a memory having a lookup table therein;
means for obtaining digital data including a data word;
means for retrieving from the lookup table a value for use in transforming the data word to form a code word;
means for transforming the data word according to the retrieved lookup table value to form the code word; and,
means for generating an RF signal derived from the code word.

12. A decoder for decoding of spread spectrum encoded data comprising:
means for providing a memory having a lookup table therein;
means for receiving an RF signal including a spread spectrum signal encoded therein; and,
means for using a lookup table to decode the encoded digital spread spectrum signal to determine at least some of the values encoded to form the encoded spread spectrum signal, the values encoded provided as an output value from the decoder.
